(19) United States
(12) Patent Application Publication
(10) Pub. No.: US 2012/0319071 A1
(43) Pub. Date: Dec. 20, 2012

(54) NON-VOLATILE SEMICONDUCTOR MEMORY DEVICE AND MANUFACTURING METHOD THEREOF

(76) Inventors: Nobuyoshi AWAYA, Osaka-shi (JP); Takahiro SHIBUYA, Osaka-shi (JP); Takashi NAKANO, Osaka-shi (JP); Yoshiaki TABUCHI, Osaka-shi (JP); Yushi INOUE, Osaka-shi (JP); Yukio TAMAI, Osaka-shi (JP)

(21) Appl. No.: 13/495,650

(22) Filed: Jun. 13, 2012

(30) Foreign Application Priority Data
Jun. 15, 2011 (JP) 2011-133061

(51) Int. Cl. H01L 45/00

(52) U.S. Cl. 257/4; 438/381; 257/E45.002

(57) ABSTRACT

The present invention provides a variable resistive element that can perform a stable switching operation at low voltage and low current, and also provides a low-power consumption large-capacity non-volatile semiconductor memory device including the variable resistive element. The non-volatile semiconductor memory device is a device using a variable resistive element, which includes a variable resistor between a first electrode and a second electrode, for storing information, wherein an oxygen concentration of a hafnium oxide (HfOₓ) film or a zirconium oxide (ZrOₓ) film constituting the variable resistor is optimized such that a stoichiometric composition ratio x of oxygen to Hf or Zr falls within a range of 1.7≦x≦1.97.

### CROSS REFERENCE TO RELATED APPLICATION

This Nonprovisional application claims priority under 35 U.S.C. §119(a) on Patent Application No. 2011-133061 filed in Japan on Jun. 15, 2011 the entire contents of which are hereby incorporated by reference.

### BACKGROUND OF THE INVENTION

1. Field of the Invention

The present invention relates to a non-volatile semiconductor memory device using a variable resistive element storing information based upon an electric operating characteristic in which a resistance changes due to application of electric stress, and a manufacturing method thereof.

2. Description of the Related Art

A non-volatile memory represented by a flash memory has widely been used for a computer, communication, measuring device, automatic control device, and device for daily use in a personal life, as a high-capacity and compact information recording medium. A demand for an inexpensive and high-capacity non-volatile memory has been extremely increased. The reason of this is as follows. Specifically, the non-volatile memory is electrically rewritable, and further, data is not erased even if a power supply is turned off. From this viewpoint, it can exhibit a function as a memory card or a cellular phone that is easy to carry, or a data storage or a program storage that stores data as an initialization upon starting a device in a non-volatile manner.

However, in the flash memory, it takes time to perform an erasing action of erasing data to a logical value “0”, compared to a programming action for programming a logical value “1”. Therefore, the erasing action is performed on a block basis in order to speed up the action. However, there arises a problem that writing by random access cannot be performed during the erasing action since the erasing action is performed on a block basis.

In view of this, a novel non-volatile memory alternative to the flash memory has widely been studied in recent years. A resistance random access memory utilizing a phenomenon in which a resistance is changed by application of voltage to a metal oxide film is more advantageous than the flash memory in microfabrication limit. The resistance random access memory can also operate at low voltage, and can write data with high speed. Therefore, research and development have actively been made in recent years (e.g., see National Publication of Japanese Translation of PCT Application No. 2002-537627, or H. Pagnia et al, “Bistable Switching in Electroformed Metal-Insulator-Metal Devices”, Phys. Stat. Sol. (a), Vol. 108, pp. 11-65, 1988, and Baek, I. G. et al, “Highly Scalable Non-volatile Resistive Memory using Simple Binary Oxide Driven by Asymmetric Unipolar Voltage Pulses”, IEDM 2004, pp. 587-590, 2004).

Since the programming and erasing actions can be performed at low voltage with high speed, the resistance random access memory using the variable resistive element having the metal oxide can write data at an optional address with high speed. The resistance random access memory can also use the data, which has conventionally been used after being temporarily loaded on a DRAM, directly from the non-volatile memory, thereby being expected to reduce power consumption and enhance usability of a mobile device.

As for programming and erasing characteristics of the variable resistive element having the metal oxide, pulses having different polarities are applied to increase (high resistance state) or decrease (low resistance state) the electric resistance of the element, in a driving method called bipolar switching. Therefore, the variable resistive element is used as a non-volatile memory by assigning a logical value to the respective resistance states as data.

Examples of the metal oxides used for the above variable resistive element include metal oxides having a perovskite structure represented by praseodymium calcium manganese oxide Pr₁₋ₓCaₓMnO₃(PCMO), and binary metal oxides such as nickel oxide, titanium oxide, or hafnium oxide.

The use of the binary metal oxides has an advantage of easy microfabrication, and reduced cost for the manufacture, since the binary metal oxides are made of materials used in a conventional semiconductor production line.

In order to realize satisfactory resistance switching by using the binary metal oxides described above, the variable resistance element is formed to be asymmetric in which a thin film of the metal oxide is sandwiched by metal electrodes, and an interface between one of the metal electrodes at both ends and the oxide becomes an ohmic junction or a state close to the ohmic junction, while an interface between the other metal electrode and the oxide becomes a state such as a schottky junction where a gap of conductive carriers is caused. With this configuration, the resistance state of the variable resistive element is changed between the high resistance state and the low resistance state by the application of voltage pulses having different polarities. Accordingly, satisfactory bipolar switching can be realized.

C. Y. Lin, et al, “Effect of Top Electrode Material on Resistive Switching Property of ZrO2 Film Devices”, IEEE Electron Device Letter, Vol. 28, No. 5, 2007, pp. 366-368 (hereinafter referred to as Known Document 1), and S. Lee, et al, “Resistance Switching Behavior of Hafnium Oxide Films Grown by MOCVD for Non Volatile Memory Application”, Journal of Electrochemical Society, 155, (2), H92-H96, (2008) (hereinafter referred to as Known Document 2) describe respectively a variable resistive element using Pt for one electrode, and satisfactory bipolar switching is possible for zirconium oxide and hafnium oxide. In Known Document 1, the bipolar switching is realized by sandwiching the zirconium oxide, which is deposited by sputtering, between a Pt electrode and a Ti electrode. On the other hand, in Known Document 2, the bipolar switching is realized by sandwiching the hafnium oxide, which is deposited by MOCVD, between a Pt electrode and an Au electrode, although the number of times of writing is one.

International Publication No. WO2009/136467 describes that an element realizing satisfactory bipolar switching is an element in which the hafnium oxide (HfOₓ) having an oxygen defect are sandwiched by different metal oxides, and which satisfies V1<V2 and V0<V2, where normal electrode potentials of two metal electrodes are defined as V1 and V2, and the electrode potential of the hafnium is defined as V0. This publication also describes that the optimal characteristic is obtained at an oxygen concentration in which x (stoichiometric composition ratio of oxygen to hafnium) in HfOₓ satisfies 0.9≦x≦1.6.

When the metal oxide having a relatively small band gap such as titanium oxide is used as the metal oxide, an electrode having a large work function such as platinum has to be used in order to form a schottky barrier at the interface with the electrode. On the other hand, when an oxide having a large band gap such as hafnium oxide or zirconium oxide is used, a satisfactory schottky barrier can be formed by using an inexpensive material that is easy to be processed for electrodes, such as titanium nitride (TiN), whereby a satisfactory switching characteristic can be obtained, which is advantageous for integration.

In H. Y. Lee, et al, “Low Power and High Speed Bipolar Switching with A Thin Reactive Ti Buffer Layer in Robust HfO₂ Based RRAM” IEDM 2008, pp. 297-300, it is confirmed that satisfactory bipolar switching is realized in a structure having hafnium oxide that is formed by ALD (Atomic Layer Deposition) and that is sandwiched by Ti and titanium nitride.

In order to utilize the variable resistive element using the metal oxide for a large-capacity semiconductor memory device, the variable resistive element has to be adapted to the leading-edge microfabrication technique. For this reason, it is necessary that the data retained in the variable resistive element can be written or read with the driving capacity of the minimum transistor manufactured by the leading-edge processing technique. Specifically, it is necessary that the resistance state of the element is changed under the condition of a low voltage of about 1 V and low current of several tens of microamperes.

In the variable resistive element using the binary metal oxide such as hafnium oxide, it is said that the resistance change is produced by opening and closing a conductive path (hereinafter referred to as “filament path”) generated by an oxygen defect formed in the oxide film in a filament form. The filament path is formed as a result of a soft breakdown by limiting current during a dielectric breakdown through voltage application called forming.

Accordingly, the narrower the thickness of the filament path is, the more the current required for the switching, i.e., the current necessary for opening and closing the filament path that is the cause of the resistance switching is reduced.

When voltage is applied to the variable resistive element from an external power source to carry out the forming, the lower limit of the current necessary for opening and closing the formed filament path is about 1 mA. This is because it is difficult to control the influence of current spike to a parasitic capacitance during the forming.

On the other hand, when the amount of current flowing through the variable resistive element during the forming is limited by using a microfabricated transistor close to the variable resistive element on the same chip, the current spike that charges the parasitic capacitance can drastically be reduced. Therefore, the lower limit of the current necessary for opening and closing the formed filament path can be reduced to about 100 μA to 200 μA.

On the other hand, in the variable resistive element using hafnium oxide or zirconium oxide, it is difficult to reduce the current required for the switching to be not more than about 100 μA to 200 μA only by the current control by the transistor. This is based upon the reason described below. Specifically, these metal oxides have a band gap large enough for forming a satisfactory schottky barrier even by a metal having a small work function such as TiN compared to Pt. This means that the coupling between the metal and oxygen is very strong. In order to form the filament path, a certain level of voltage and current for breaking the coupling between the metal and oxygen have to be applied to move the oxygen. However, in the metal oxide having very strong coupling between metal and oxygen, such as hafnium oxide and zirconium oxide, the amount of applied voltage and current necessary for forming the filament path is large. Therefore, it is difficult to form a small filament path, which means it is difficult to reduce the switching current.

### SUMMARY OF THE INVENTION

The present invention is accomplished in view of the above problems, and aims to provide a variable resistive element using hafnium oxide or zirconium oxide, and capable of realizing a stable switching operation with low voltage and low current, and to provide a large-capacity low-power consumption non-volatile semiconductor memory device using the variable resistive element.

In order to achieve the foregoing object, the non-volatile semiconductor memory device according to the present invention employs a variable resistive element for storing information, the variable resistive element including: a variable resistor made of a metal oxide, and a first electrode and a second electrode that sandwich the variable resistor, an electric resistance between both electrodes of the variable resistive element being reversibly changed due to application of voltage to between the both electrodes, wherein the first electrode is made of a conductive material and the second electrode is made of a conductive material having a different work function from that of the first electrode, the metal oxide is hafnium oxide or zirconium oxide, and the metal oxide has a stoichiometric composition ratio x of oxygen to a metal constituting the metal oxide, the ratio x falling within a range of 1.7≦x≦1.97.

In the non-volatile semiconductor device according to the above aspect of the present invention, it is preferable that the stoichiometric composition ratio x of oxygen of the metal oxide falls within the range of 1.84≦x≦1.92.

In the non-volatile semiconductor device according to the above aspect of the present invention, it is preferable that, in the variable resistive element, a satellite peak at a low-energy side at K-absorption edge of oxygen in an electron energy-loss spectrum of the metal oxide is not observed, or the intensity of the satellite peak at a peak position is less than 0.78 times as small as a main peak.

In the non-volatile semiconductor device according to the above aspect of the present invention, it is preferable that, by performing a forming process, a resistance state between the first electrode and the second electrode of the variable resistive element is changed from an initial high resistance state before the forming process to a variable resistance state; the resistance state in the variable resistance state is changed between two or more different resistance states by application of voltage to the first electrode and the second electrode of the variable resistive element in the variable resistance state, and one of the resistance states after the change is used for storing information; and a density of current flowing through the variable resistive element in the initial high resistance state at the time of application of an electric field of 4 MV/cm to the variable resistor falls within a range of 0.04 to 80 A/cm².

In the non-volatile semiconductor device according to the above aspect of the present invention, it is preferable that the first electrode is made of a conductive material having a work function smaller than 4.5 eV, and the second electrode is made of a conductive material having a work function of not less than 4.5 eV.

In the non-volatile semiconductor device according to the above aspect of the present invention, it is preferable that the first electrode includes any of conductive materials of Ti, Ta, Hf, and Zr.

In the non-volatile semiconductor device according to the above aspect of the present invention, it is preferable that the second electrode includes any of conductive materials of TiN, Pt, Ru, RuO₂, and ITO.

In order to achieve the foregoing object, a manufacturing method of a non-volatile semiconductor device according to the present invention is a method of manufacturing the non-volatile semiconductor device according to the above aspect of the present invention, wherein the metal oxide is formed by a sputtering method using an oxide of a metal constituting the metal oxide or a metal constituting the metal oxide as a target under an inert gas atmosphere.

In the manufacturing method of the non-volatile semiconductor device according to the above aspect of the present invention, it is preferable that the metal oxide is formed by the sputtering method using the oxide of the metal constituting the metal oxide as a target under the inert gas atmosphere not containing oxygen gas as additive gas.

In the present invention, an oxygen defect with the optimum concentration is formed in the hafnium oxide (HfOₓ) film or in the zirconium oxide (ZrOₓ) film so as to allow oxygen to easily move. This structure facilitates to open and close a filament path, whereby voltage and current required for a switching operation can be reduced.

It is found from a first principle calculation that energy required to break a bond of one oxygen from hafnium oxide, which is ideally defect-free, so as to form an oxygen defect is very high such as 6.16 eV. On the other hand, it is found that oxygen can go over a potential barrier with low energy such as 1.96 eV on the shortest route in the film having the oxygen defect.

A perfect defect-free oxide is not present in nature. It has widely been known that a stoichiometric composition ratio of hafnium oxide or zirconium oxide is shifted toward the lack of oxygen in nature, and hafnium oxide or zirconium oxide is classified into an n-type metal oxide having n-type conductive property due to an oxygen defect. Accordingly, a film formed by a general process has an oxygen defect. The inventors of the present application have made earnest studies, and have derived, from an experiment, a desirable oxygen defect concentration that facilitates the movement of oxygen in the above-mentioned film, and that forms a film having a property capable of attaining a switching operation with low current.

As a result of the experiment, the inventors of the present application have proved that, by using a film having an oxygen defect, and having a stoichiometric composition ratio x of oxygen in hafnium oxide (HfOₓ) falling within the range of 1.7≦x≦1.97, oxygen is easy to move, and the filament path is easy to be opened and closed, whereby voltage and current required for the switching operation is reduced.

The process that can easily form a film in non-equilibrium state, such as the sputtering method, is used for forming a film of the metal oxide so as to form the hafnium oxide film or the zirconium oxide film that has the stoichiometric composition ratio falling within the above-mentioned range. Accordingly, the metal oxide film that has insufficient oxygen can be used as a material for changing a resistance of a resistance change element.

Consequently, according to the present invention, a variable resistive element that can realize a stable switching operation with low voltage and low current can be realized by using hafnium oxide or zirconium oxide, whereby a large-capacity non-volatile semiconductor memory device using the variable resistive element can be realized.

### BRIEF DESCRIPTION OF THE DRAWINGS

FIG. 1 is a schematic sectional view illustrating one example of a structure of a variable resistive element used in the present invention;

FIG. 2 is a table illustrating combinations of electrodes that can perform resistance switching, and switching properties thereof in the variable resistive element according to the present invention;

FIG. 3 is a table illustrating a normal electrode potential and a work function of a metal constituting an electrode of the variable resistive element;

FIG. 4 is a graph illustrating a relationship between a flow rate of oxygen gas added to Ar gas and an oxygen concentration of a formed film during film formation of an hafnium oxide film by a sputtering method;

FIG. 5 is a view illustrating volt-ampere characteristics of the variable resistive element, including a film formed by sputtering a hafnium oxide target without addition of oxygen as a variable resistor, during a forming process;

FIG. 6 is a view illustrating volt-ampere characteristics of the variable resistive element, including a film formed by sputtering a hafnium oxide target with addition of 5 sccm oxygen as a variable resistor, during a forming process;

FIG. 7 is a view illustrating volt-ampere characteristics of the variable resistive element, including a hafnium oxide film formed by an ALD process as a variable resistor, during a forming process;

FIG. 8 is a view illustrating a change in conduction activation energy of a film formed by sputtering a hafnium oxide target without addition of oxygen, during application of voltage;

FIG. 9 is a view illustrating a change in conduction activation energy of a film formed by sputtering a hafnium oxide target with addition of 5 sccm oxygen, during application of voltage;

FIG. 10 is a view illustrating a change in conduction activation energy of a film formed by an ALD process, during application of voltage;

FIG. 11 is an equivalent circuit diagram illustrating one example of a memory cell including the variable resistive element according to the present invention;

FIG. 12 is a view illustrating a switching characteristic and current flowing during the switching operation of the variable resistive element including a film, which is formed by sputtering a hafnium oxide target without addition of oxygen, as a variable resistor;

FIG. 13 is a view illustrating a switching characteristic and current flowing during the switching operation of the variable resistive element including a film, which is formed by sputtering a hafnium oxide target with addition of 5 sccm oxygen, as a variable resistor;

FIG. 14 is a view illustrating dependency of current flowing during a reset operation of the variable resistive element depending upon a film-forming condition of the hafnium oxide film (variable resistor film);

FIG. 15 is a view illustrating dependency of current flowing during a reset operation of the variable resistive element depending upon a thickness of the hafnium oxide film (variable resistor film), and a switching operating condition;

FIG. 16 is a graph illustrating a relationship between a flow rate of oxygen gas added to Ar gas and an oxygen concentration of a formed film during film formation of an hafnium oxide film by a reactive sputtering method under an oxidation atmosphere;

FIG. 17 is a view illustrating volt-ampere characteristics of the variable resistive element, including a film formed by sputtering a metal hafnium target with addition of 4.5 sccm oxygen as a variable resistor, during a forming process;

FIG. 18 is a view illustrating dependency of current flowing during a reset operation of the variable resistive element depending upon a film-forming condition of the hafnium oxide film (variable resistor film);

FIG. 19 is a view illustrating a relationship between the switching characteristic of the variable resistive element and an oxygen concentration of the hafnium oxide film (variable resistor film);

FIG. 20 is a view illustrating a relationship between an applied electric field and the current density of the variable resistive element of the present invention before the forming process;

FIGS. 21A and 21B are views illustrating an electron energy-loss spectrum of the hafnium oxide film;

FIG. 22 is a view illustrating a change in an intensity ratio of a satellite peak at an oxygen K-absorption edge in the electron energy-loss spectrum according to the stoichiometric composition ratio of the oxygen in the hafnium oxide film;

FIGS. 23A and 23B are views illustrating an electron energy-loss spectrum of the zirconium oxide film;

FIG. 24 is a circuit block diagram illustrating a schematic configuration of a non-volatile semiconductor memory device according to the present invention; and

FIG. 25 is a circuit diagram illustrating a schematic configuration of a memory cell array including the variable resistive element according to the present invention.

### DESCRIPTION OF THE PREFERRED EMBODIMENTS

### First Embodiment

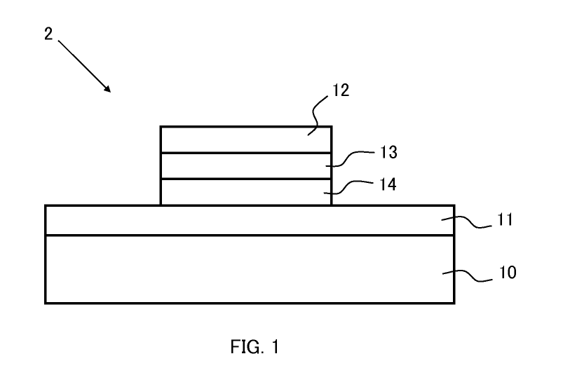

FIG. 1 is a sectional view schematically illustrating a structure of a variable resistive element 2 used in a non-volatile semiconductor memory device (hereinafter appropriately referred to as “present device 1”) according to one embodiment of the present invention. In the drawings described below, essential parts are emphasized for the sake of convenience of description, and a dimensional ratio of each component of the element and an actual dimensional ratio do not agree with each other in some cases.

The variable resistive element 2 includes a second electrode (lower electrode) 14, a variable resistor 13 made of a metal oxide film, and a first electrode (upper electrode) 12, those of which are deposited and patterned in this order on an insulating film 11 formed on a substrate 10. The variable resistive element 2 has a schottky interface formed at the interface between the second electrode 14 and the variable resistor 13. The variable resistive element 2 is configured such that an electronic state in the vicinity of the interface reversibly changes due to application of electric stress, whereby the resistance is changed. The variable resistor 13 is made of hafnium oxide (HfOₓ), and its oxygen concentration (stoichiometric composition ratio of oxygen to hafnium) x is adjusted to fall within a range of 1.7≦x≦1.97.

The initial resistance immediately after manufacture of the variable resistive element 2 employing the metal oxide as the variable resistor 13 is extremely high. In order to allow the variable resistive element 2 to have a state (variable resistance state) in which the resistance state can be changed between a high resistance state and a low resistance state by electric stress, it is necessary to perform a so-called forming process before the variable resistive element is used. Specifically, in the forming process, a voltage pulse, which has a voltage amplitude larger than that of a voltage pulse used for a normal writing action and has a pulse width longer than that of the same voltage pulse, is applied to the variable resistive element, which is immediately after being manufactured and has the initial resistance state, so as to form a current path where resistance switching occurs. It is known that a conductive path (filament path) formed by the forming process determines the subsequent electric property of the element.

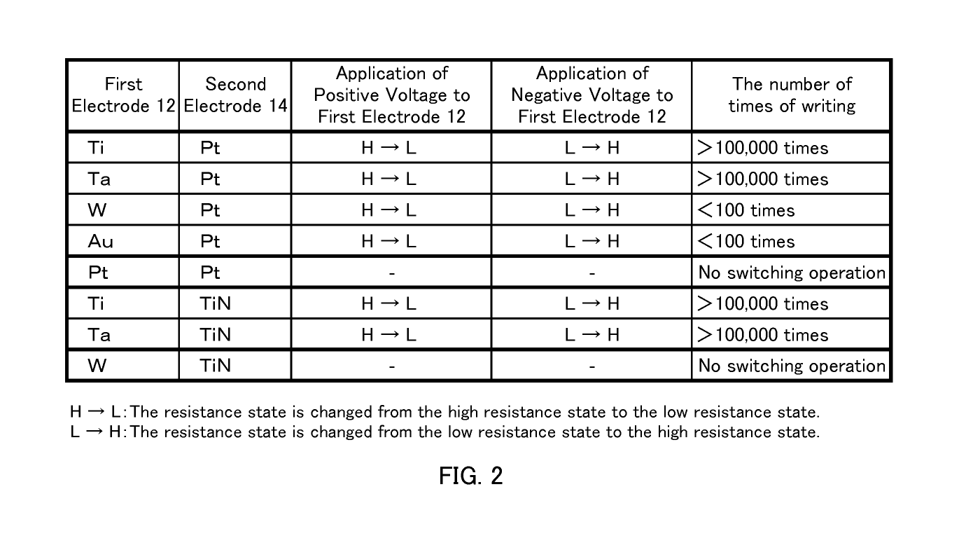

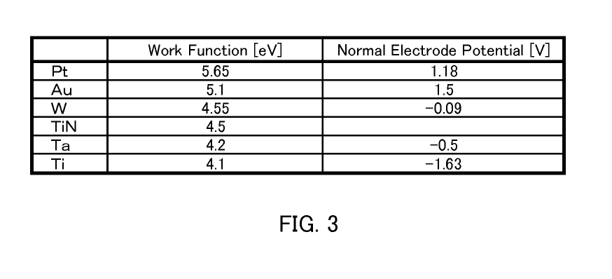

FIG. 2 illustrates combinations of the first electrode 12 and the second electrode 14 that can perform resistance switching, and switching properties thereof. FIG. 3 is a table illustrating a normal electrode potential and a work function of an individual metal constituting the electrodes 12 and 14 in FIG. 2.

When Pt is used for the second electrode 14, a bipolar switching operation can be confirmed even in any cases where Ti, Ta, W, and Au are used for the first electrode 12, regardless of a later-described process of forming a hafnium oxide film. In this case, the relationship between the polarity of the applied voltage pulse and the resistance change are the same. Specifically, when a voltage pulse that is a positive voltage with the second electrode 14 being defined as a reference is applied to the first electrode 12, the resistance state of the variable resistive element 2 becomes a low resistance state, and when a voltage pulse that is a negative voltage with the second electrode 14 being defined as a reference is applied to the first electrode 12, the resistance state of the variable resistive element 2 becomes a high resistance state.

It can be seen from FIG. 3 that Au has higher normal electrode potential than Pt. If the operating characteristic of the bipolar switching is determined by the normal electrode potential, the polarity for the variable resistive element using Au for the first electrode must be opposite to the polarity for the variable resistive element using other metals, such as Ti, Ta, and W, having the normal electrode potential lower than that of Pt. However, this did not happen.

On the other hand, Pt has the highest work function. If the operating characteristic of the bipolar switching is determined by the work function, the experimental result in FIG. 2 is consistent with this result. When the difference in the switching characteristic between materials used for the first electrode 12 in FIG. 2 is considered, the following points are pointed out: (1) in the variable resistive element using Ti and Ta having a small work function, hundred thousand or more resistance changes can stably be executed, but in the variable resistive element using W or Au having a work function smaller than that of Pt but larger than that of Ti or Ta, the writing action is performed only 100 times or less, which indicates unstable switching; and (2) when TiN is used for the second electrode 14, the switching operation is possible for Ti and Ta having a work function smaller than that of TiN, but the switching operation is not performed in the variable resistive element using W having a work function larger than that of TiN. These points suggest that the bipolar switching operation is determined by the work function of the electrode, and the normal electrode potential is unrelated to the bipolar switching operation.

More specifically, a variable resistive element having a satisfactory bipolar switching characteristic can be realized by selecting conductive materials for both electrodes such that the first electrode 12 has a work function smaller than 4.5 eV and the second electrode 14 has a work function not less than 4.5 eV. Examples of the conductive material forming the first electrode 12 include Hf (3.9 eV), and Zr (4.1 eV) in addition to Ti and Ta described above (the value in each parenthesis indicates a work function of the corresponding metal). Similarly, examples of the conductive material forming the second electrode 14 include Ru, RuO₂, and ITO (Indium Tin Oxide) in addition to Pt and TiN described above.

Among the electrode materials illustrated in FIG. 2, the combination of Ti or Ta for the first electrode 12 and TiN for the second electrode 14 is preferable from the viewpoint of easiness in integration processing.

As for the film-forming process of the variable resistor 13, the sputtering method that enables film formation under a non-equilibrium state is preferably used in order to control the oxygen defect concentration of the metal oxide film. In the present embodiment, hafnium oxide (HfO₂) containing just enough oxygen is used as a sputter target, and a film is formed in an argon (Ar) gas atmosphere by high-frequency sputtering (applied voltage: 500 W).

During the formation of the hafnium oxide film by the above-mentioned sputtering method, a film formed by adding oxygen gas to the Ar gas, and a film formed by ALD (Atomic Layer Deposition) were prepared, and an oxygen concentration, film quality, and electric property of each film were measured and compared. The result is described below.

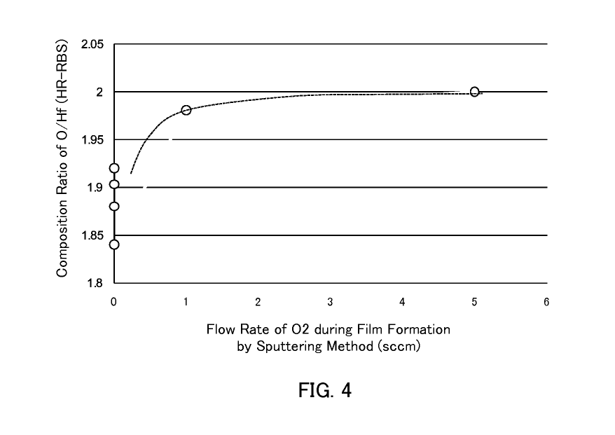

FIG. 4 illustrates the result of the measurement of the oxygen composition ratio of each film, which was formed by changing an additive amount of oxygen gas in the sputtering, according to high resolution Rutherford backscattering (HR-RBS).

The hafnium oxide film was formed under the film-forming condition described below.

Film-forming condition #1: The hafnium oxide target was sputtered with 20 sccm flow rate of Ar, so as to form a film.

Film-forming condition #2: The hafnium oxide target was sputtered by adding 1 sccm oxygen to Ar in the flow rate of 20 sccm, so as to form a film.

Film-forming condition #3: The hafnium oxide target was sputtered by adding 5 sccm oxygen to Ar in the flow rate of 20 sccm, so as to form a film.

Film-forming condition #4: A film was formed by the ALD process. The hafnium oxide films formed under the film-forming conditions #1 to #4 are respectively referred to as variable resistor films 13a to 13d below. Variable resistive elements including the variable resistor films 13a to 13d are respectively referred to as variable resistive elements 2a to 2d.

In the sputter film using the hafnium oxide target, the content of oxygen increases as the additive amount of oxygen is increased, wherein the composition thereof becomes close to the composition of the ALD film in which the stoichiometric composition ratio x of oxygen to Hf is approximately 2. When the film is formed by the sputtering method without addition of oxygen, the oxygen concentration varies depending upon the processing history of the sputtering device. However, the ratio of oxygen to hafnium is 92 to 96% of the ratio of oxygen to hafnium of the ALD film, which shows that this film has lower oxygen concentration compared to the sputter film formed with the addition of oxygen and the film formed by the ALD process. The x of HfOₓ, which is the stoichiometric composition ratio of oxygen to Hf, falls within the range of 1.84≦x≦1.92.

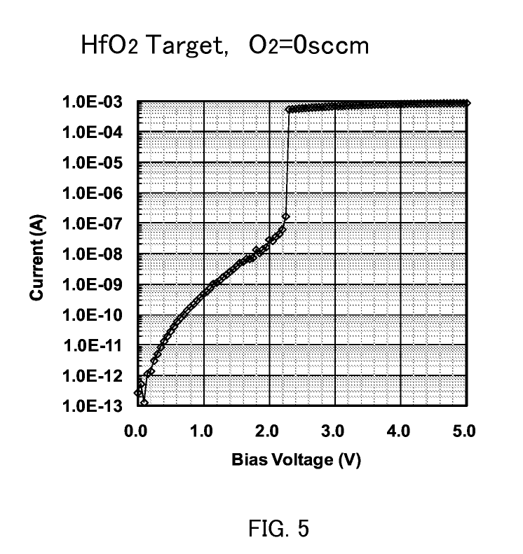

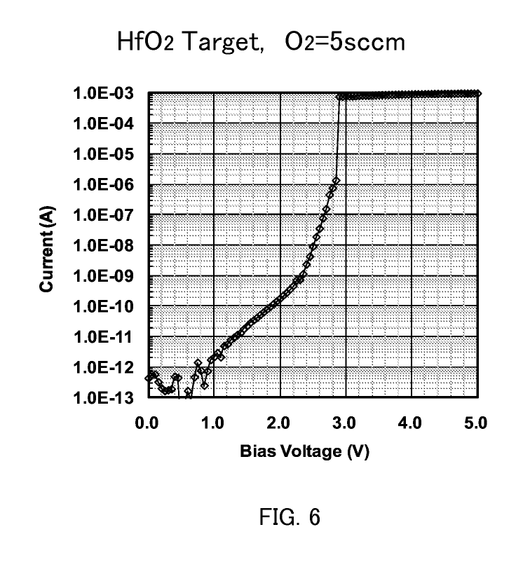

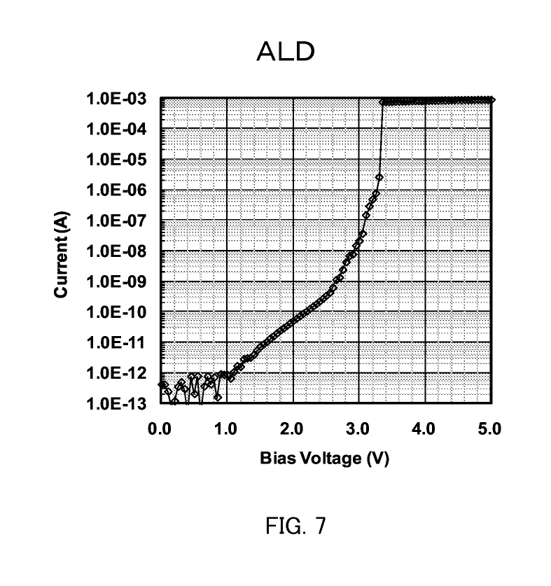

FIGS. 5 to 7 illustrate volt-ampere characteristics of the variable resistive elements 2, each including the hafnium oxide film formed under the different film-forming condition as a variable resistor 13, during a forming process. The measured element has a MIM structure in which an area is 5 μm×5 μm, HfOₓ with a thickness of 5 nm is used, TiN is used for the second electrode (lower electrode) 14, and Ta is used for the first electrode (upper electrode) 12. FIG. 5 illustrates the volt-ampere characteristics of the variable resistive element 2a having the variable resistor film 13a, FIG. 6 illustrates the volt-ampere characteristics of the variable resistive element 2c having the variable resistor film 13c, and FIG. 7 illustrates the volt-ampere characteristics of the variable resistive element 2d having the variable resistor film 13d formed by the ALD process. In each figure, the forming process is completed at the voltage where current sharply changes. That is, each variable resistive element changes from the initial high resistance state to the variable resistance state in which the resistance change is possible.

When voltage is applied to the respective variable resistive elements 2a, 2c, and 2d, non-linear current flows in each element. Comparing the currents flowing through the respective variable resistive elements 2a, 2c, and 2d, the currents flowing through the variable resistive element 2c and 2d are almost equal. However, it is found that current about 1000 times as large as the currents flowing through the variable resistive elements 2c and 2d flows through the variable resistive element 2a having the film, which is formed by sputtering the hafnium oxide target without addition of oxygen with 20 sccm flow rate of Ar, at the voltage of 1 V, and current about 100 times as large as the current flowing through the variable resistive elements 2c and 2d flows through the variable resistive element 2a at the voltage of 2 V.

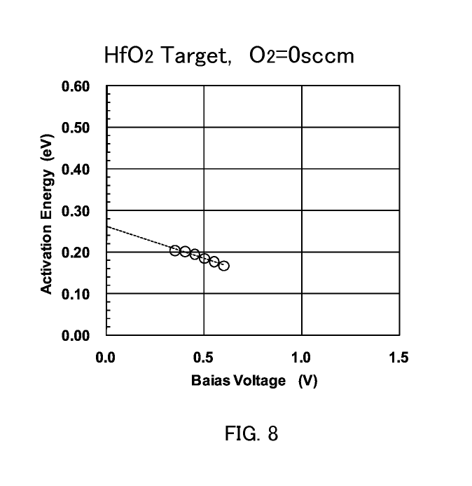

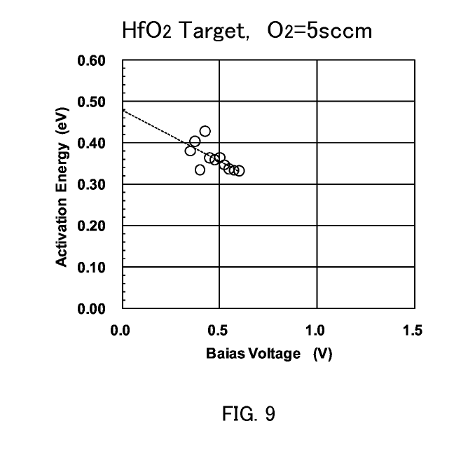

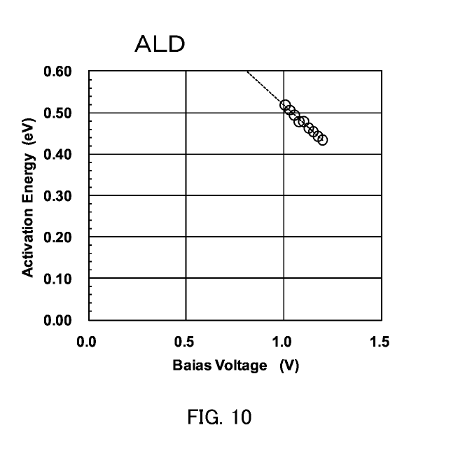

It was confirmed that the conduction mechanism on the formed hafnium oxide films was the conduction of electrons through the oxygen defect, and was Poole-Frenkel hopping conduction. Supposing that the conduction mechanism is represented by a Poole-Frenkel model, FIGS. 8 to 10 are views illustrating the results of activation energy of the conduction of each hafnium oxide film. FIGS. 8 to 10 illustrate the activation energy of the conduction of each of the variable resistor film 13a, the variable resistor film 13c, and the variable resistor film 13d during the application of voltage. The activation energy under each of voltage application conditions is calculated from the temperature dependency of current under each applied voltage based upon the Poole-Frenkel model, so as to obtain the extrapolated activation energy when the applied voltage is zero.

It can be seen from FIGS. 8 to 10 that, without the application of voltage, the activation energy of the variable resistor film 13a formed by sputtering the hafnium oxide target with 20 sccm flow rate of Ar was 0.2 to 0.3 eV, the activation energy of the variable resistor film 13c formed by sputtering the hafnium oxide target with addition of 5 sccm oxygen to Ar at a flow rate of 20 sccm was 0.4 to 0.6 eV, and the activation energy of the variable resistor film 13d formed by the ALD process was 0.9 to 1.0 eV. This shows that the activation energy of the hopping conduction decreases with the decrease in oxygen. It has been known that the activation energy becomes close to 1 eV when the hafnium oxide becomes close to HfO₂ having the ideal stoichiometric composition ratio, i.e., HfO₂ containing just enough oxygen. It is considered that the sample formed by the ALD process is close to the HfO₂ having the ideal stoichiometric composition ratio.

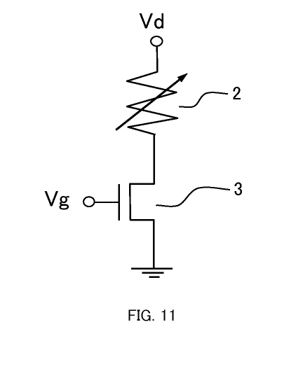

Next, the result of the experiments of the resistance switching characteristics of the variable resistive elements 2a to 2d will be described. The experiments of the resistance switching were carried out by using a memory cell illustrated in an equivalent circuit diagram in FIG. 11 and having a transistor 3 connected in series.

In this case, the forming operation for forming the filament path first, and the set operation of changing the resistance state from the high resistance state to the low resistance state are each performed by applying voltage Vg to a gate of the transistor 3 so as to limit the current flowing through the variable resistive element, as shown in FIG. 11. In the present embodiment, the drive current of the transistor 3 was limited to 60 μA, and the applied voltage Vd was swept from 0 V to 6 V during the forming operation, whereby the filament was formed. On the other hand, during the set operation for changing the resistance state from the high resistance state to the low resistance state, the drive current of the transistor 3 was limited to 100 μA, Vd was fixed to 3 V, and a set voltage pulse was applied with the applying time of 50 ns. On the other hand, during the reset operation for changing the resistance state from the low resistance state to the high resistance state, the gate of the transistor 3 was fully opened to allow current to flow with the maximum drive current 800 μA being defined as an upper limit. The applied voltage Vd was applied for the applying time of 80 ns, wherein the absolute value of the applied voltage Vd increased in increment of 0.1 V within −1.1 V to −3.3 V. Thus, the reset voltage pulse was applied for the applying time of 80 ns.

In the operating conditions described above, the operating current is limited by the transistor 3 during the forming operation and set operation, while the current is not limited in the reset operation. Therefore, the current flowing through the variable resistive element during the reset operation is mainly determined by the film quality of the hafnium oxide film serving as the variable resistor.

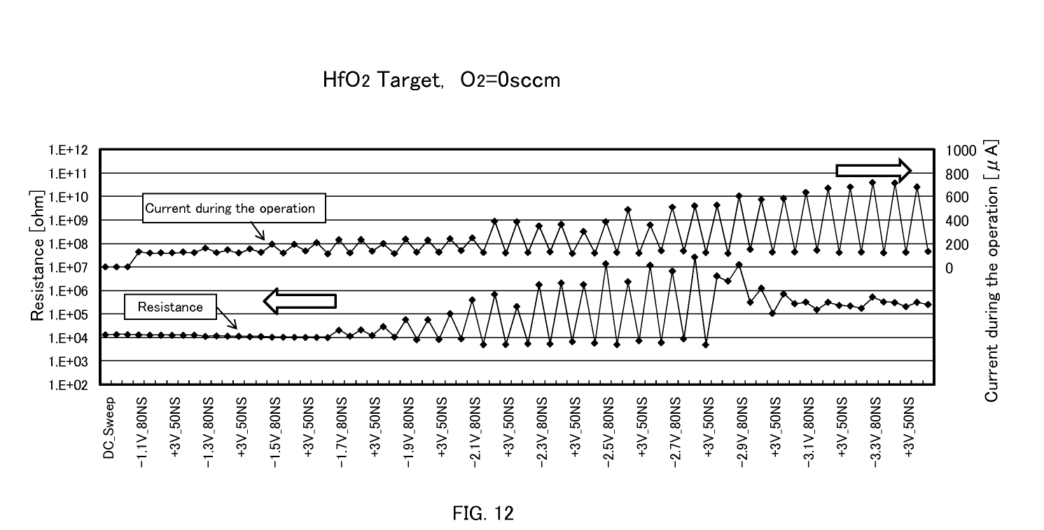

FIG. 12 illustrates the resistance change (a lower line graph) of the variable resistive element 2a when the set voltage pulse is fixed under the above condition, and the absolute value of the amplitude of the reset voltage pulse is increased in increment of 0.1 V, and the change in the current (upper line graph) flowing during the operation. It can be seen that the switching is started when the reset voltage is 1.7 V or more, that the resistance change ratio increases with the increase in the reset voltage, and the switching becomes unstable when the reset voltage is 2.7 V or more. The reset current is about 200 μA at the reset voltage of 1.7 V where the resistance change is started, and is about 600 μA at the reset voltage of 2.9 V where the switching becomes unstable.

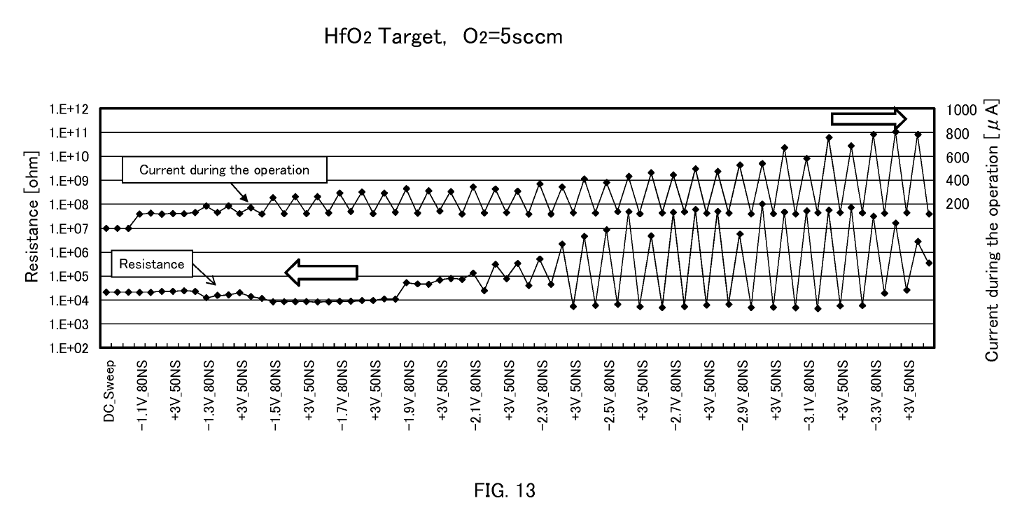

FIG. 13 illustrates, similarly in FIG. 12, the resistance change (a lower line graph) of the variable resistive element 2c when the set voltage pulse is fixed under the above condition, and the absolute value of the voltage amplitude of the reset voltage pulse is increased in increment of 0.1 V, and the change in the current (upper line graph) flowing during the operation. It can be seen that the switching is started when the reset voltage is 2.1 V or more, that the resistance change ratio increases with the increase in the reset voltage, and the switching becomes unstable when the reset voltage is 3.3 V or more. The reset current is about 300 μA at the reset voltage of 2.1 V where the resistance change is started, and is about 800 μA at the reset voltage of 3.3 V where the switching becomes unstable.

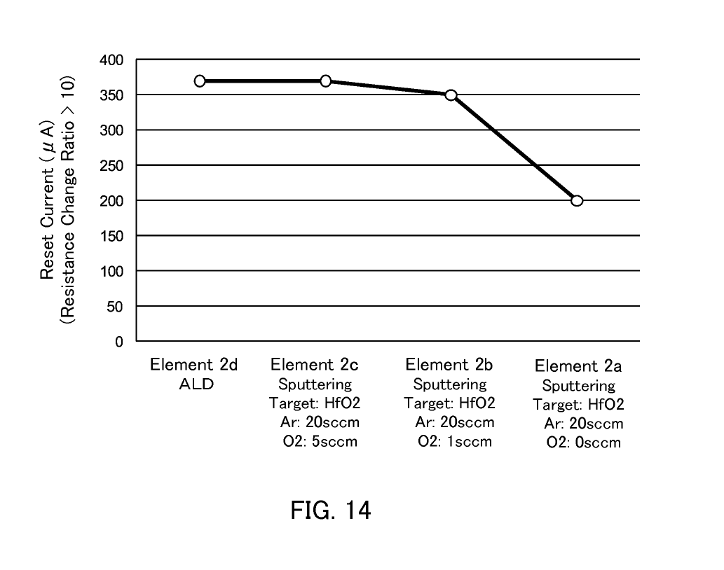

FIG. 14 illustrates currents flowing during the reset operation when the resistance change ratio (the ratio of the resistance value of the high resistance state and the resistance value of the low resistance state) of the respective variable resistive elements 2a to 2d is 10 or more. It can be seen that the variable resistive elements 2b to 2d require the reset current of 350 μA or more. However, the reset current is drastically reduced to be 200 μA in the variable resistive element 2a including the hafnium oxide film formed by sputtering the hafnium oxide target with 20 sccm flow rate of Ar.

From the above, it can be seen that the reset voltage required for the resistance change can be reduced by decreasing the oxygen concentration of the hafnium oxide film, whereby the reset current can drastically be reduced.

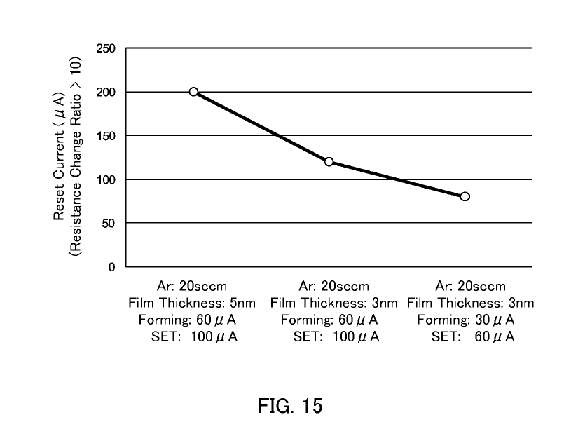

The operating current can further be reduced by optimizing the element structure or the switching operating condition. FIG. 15 is a graph illustrating the dependency of the reset current on the thickness of the variable resistor film 13a or the operating condition in the variable resistive element 2a including the variable resistor film 13a formed by sputtering the hafnium oxide target with 20 sccm flow rate of Ar. When the thickness of the variable resistor 13a was reduced to 3 nm from 5 nm, the reset current could be reduced to 120 μA. When the current flowing through the variable resistive element 2a during the forming operation was limited to be not more than 30 μA, and the set current was limited to be not more than 60 μA, the reset current could be reduced to 80 μA.

### Second Embodiment

In the first embodiment, the case in which the hafnium oxide film serving as the variable resistor 13 is formed by the sputtering method employing the hafnium oxide (HfO2) containing just enough oxygen as the sputter target has been described in detail. In the present embodiment, the hafnium oxide film is formed by a reactive sputtering method using a metal hafnium target in an oxidation atmosphere. As in the first embodiment, the film is formed by high-frequency sputtering (applied voltage: 500 W) under the argon (Ar) gas atmosphere.

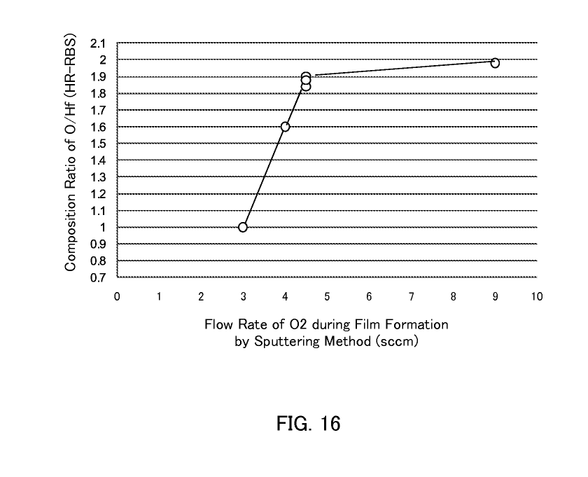

FIG. 16 illustrates the result of the measurement of the oxygen composition ratio of each film, which was formed by changing an additive amount of oxygen gas in the reactive sputtering, according to high resolution Rutherford backscattering (HR-RBS).

The hafnium oxide film was formed under the film-forming condition described below.

Film-forming condition #5: The metal hafnium target was sputtered by adding 3 sccm oxygen to Ar in the flow rate of 20 sccm, so as to form a film.

Film-forming condition #6: The metal hafnium target was sputtered by adding 4 sccm oxygen to Ar in the flow rate of 20 sccm, so as to form a film.

Film-forming condition #7: The metal hafnium target was sputtered by adding 4.5 sccm oxygen to Ar in the flow rate of 20 sccm, so as to form a film.

Film-forming condition #8: The metal hafnium target was sputtered by adding 9 sccm oxygen to Ar in the flow rate of 20 sccm, so as to form a film.

In the following, the hafnium oxide films formed under the film-forming conditions #5 to #8 are respectively referred to as variable resistor films 13e to 13h as appropriate. Variable resistive elements including the variable resistor films 13e to 13h are respectively referred to as variable resistive elements 2e to 2h.

In the variable resistor film 13e (oxygen flow rate: 3 sccm), the ratio of oxygen to hafnium was 50% of the ratio of oxygen to hafnium of the ALD film. Specifically, the x of HfOₓ, which is the stoichiometric composition ratio of oxygen to Hf, is x=1.0.

In the variable resistor film 13f (oxygen flow rate: 4 sccm), the ratio of oxygen to hafnium was 80% of the ratio of oxygen to hafnium of the ALD film. Specifically, the x of HfOₓ, which is the stoichiometric composition ratio of oxygen to Hf, is x=1.6.

In the variable resistor film 13g (oxygen flow rate: 4.5 sccm), the ratio of oxygen to hafnium was within the range of 92 to 95% of the ratio of oxygen to hafnium of the ALD film. The x of HfOₓ, which is the stoichiometric composition ratio of oxygen to Hf, falls within the range of 1.84×1.9.

In the variable resistor film 13h (oxygen flow rate: 9 sccm), the ratio of oxygen to hafnium was 99% of the ratio of oxygen to hafnium of the ALD film. Specifically, the x of HfOₓ, which is the stoichiometric composition ratio of oxygen to Hf, is x=1.98.

It can be seen that, as the additive amount of oxygen increases, the content of oxygen increases, so that the composition becomes close to the composition of the ALD film in which the stoichiometric composition ratio x of oxygen to Hf is almost equal to 2. However, only the variable resistive elements 2g and 2h including the variable resistor films 13g and 13h can perform the resistance switching. In the variable resistive elements 2e and 2f including the films formed under the condition that the flow rate of oxygen was 4 sccm or less, only the current was flown due to the voltage application, and the resistance change did not occur.

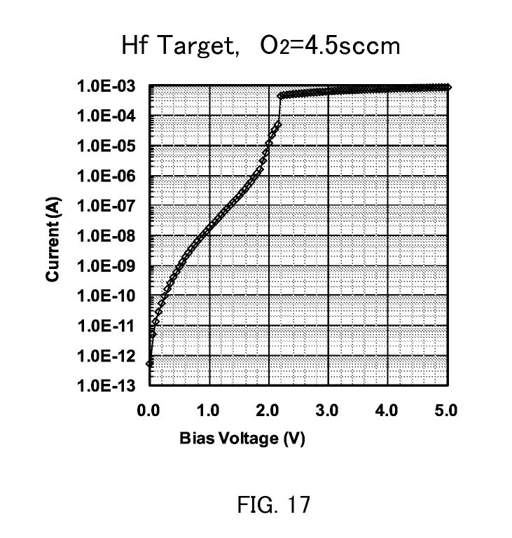

FIG. 17 illustrates the volt-ampere characteristics of the variable resistive element 2g during the forming process. The measured element has a MIM structure in which an element area is 5 μm×5 μm, HfOₓ with a thickness of 5 nm is used, TiN is used for the second electrode (lower electrode) 14, and Ta is used for the first electrode (upper electrode) 12, as in FIGS. 5 to 7 in the first embodiment. In the figure, the forming process is completed at the voltage (about 2.2 V) where current sharply changes. That is, each variable resistive element changes from the initial high resistance state to the variable resistance state in which the resistance change is possible. It can be seen from FIG. 17 that the current flowing through the variable resistive element 2g during the forming is about 10 times as large as the current flowing through the variable resistive element 2a (FIG. 5) having the film formed by sputtering the hafnium oxide target without addition of oxygen with 20 sccm flow rate of Ar at the voltage of 1 V, and is about 100 times as large as the current flowing through the variable resistive element 2a at a voltage of 2 V. The volt-ampere characteristic of the variable resistive element 2h during the forming process is almost equal to that of the variable resistive element 2d (FIG. 7) including the ALD film.

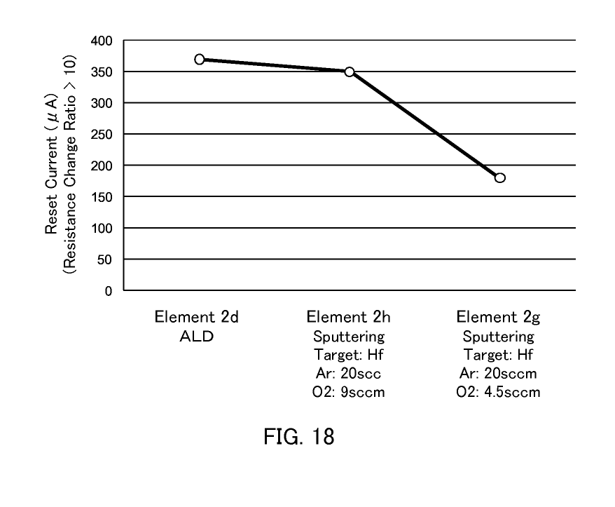

Next, the result of the experiments of the resistance switching characteristics of the variable resistive elements 2g and 2h will be described, the experiments being carried out in the same manner as for the variable resistive elements 2a to 2d. FIG. 18 corresponds to FIG. 14, and illustrates currents flowing during the reset operation when the resistance change ratio (the ratio of the resistance value of the high resistance state and the resistance value of the low resistance state) of the respective variable resistive elements 2e to 2h is 10 or more. It can be seen that the variable resistive element 2h requires the reset current of 350 μA or more. However, the reset current is drastically reduced to be 200 μA in the variable resistive element 2g including the hafnium oxide film formed by sputtering the metal hafnium target with the additive amount of 4.5 sccm of oxygen.

From the above, the switching operation cannot be performed if the oxygen concentration of the hafnium oxide film is too small. In consideration of the finding in the first embodiment, it is understood that there is a certain desirable range of the oxygen concentration of the hafnium oxide film in order to reduce the reset current.

### Third Embodiment

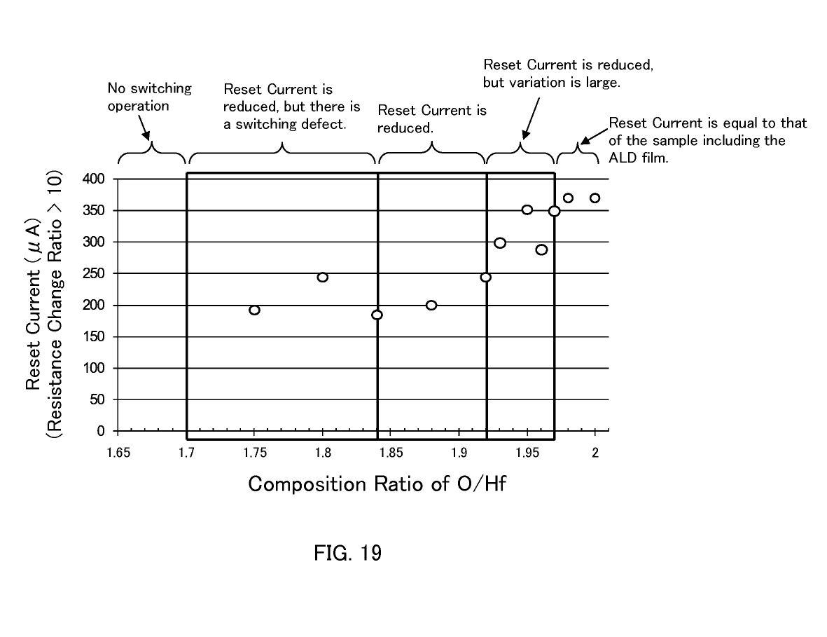

The findings in the first embodiment and the second embodiment are collectively described below. FIG. 19 is a result of comparison of the switching characteristics of the variable resistive elements 2, wherein the oxygen concentration of the hafnium oxide film is minutely changed.

Within the range of 1.97≦x≦2.0 of the stoichiometric composition ratio x of oxygen to Hf, the reset current during the switching operation was equal to that of the sample including the ALD film in which x≈2.

Within the range of 1.92≦x≦1.97 of the stoichiometric composition ratio x of oxygen to Hf, the reduction in the reset current during the switching operation was observed, but the variation in the property was generated. However, the variation in the property can be solved by the improvement in the process condition or element structure, and this range is the region where the reset current can be reduced.

Within the range of 1.84≦x≦1.92 of the stoichiometric composition ratio x of oxygen to Hf, the remarkable reduction in the reset current during the switching operation was observed, and the satisfactory switching characteristic was also observed.

Within the range of 1.7≦x≦1.84 of the stoichiometric composition ratio x of oxygen to Hf, although the reduction in the reset current during the switching operation was observed, there were elements that have a switching defect in which the satisfactory switching characteristic (here, the resistance change ratio of 10 or more) could not be realized due to the great variation in the property. However, the switching defect described above can be improved by the optimization in the operating condition such as the applied voltage pulse or the current limiting value, and by the optimization in the element structure such as the thickness or element size.

On the other hand, within the range of x<1.7 of the stoichiometric composition ratio x of oxygen to Hf, the elements were short-circuited upon the voltage application because of the property of the metal strongly appearing, so that the elements did not operate as the variable resistive elements.

Therefore, when the hafnium oxide film (variable resistor film) serving as the variable resistor is formed such that the stoichiometric composition ratio x of oxygen to Hf falls within the range of 1.7≦x≦1.97, more preferably within the range of 1.84≦x≦1.92, the variable resistive element having reduced operating current and capable of performing a stable switching operation can be realized.

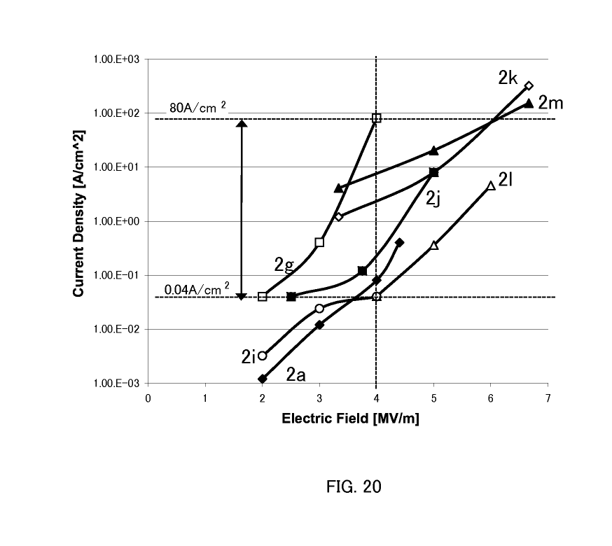

FIG. 20 illustrates the volt-ampere characteristics of the variable resistive elements 2a, 2g, and 2i to 2m in the initial high resistance state before the forming process, in terms of the relation to the current density to the applied electric field, wherein the variable resistive elements 2a, 2g, and 2i to 2m are formed such that the oxygen concentration of the hafnium oxide film falls within the above-mentioned numerical range, and they exhibit a satisfactory switching characteristic. It can be seen from FIG. 20 that the elements through which current with the current density of 0.04 to 80 A/cm² flows with respect to the electric field application of 4 MV/cm exhibit the satisfactory switching characteristic with low reset current.

The film-forming condition and element structure of each variable resistive element illustrated in FIG. 20 will be described below.

Variable resistive element 2a:1R element having an element area of 5 μm×5 μm, wherein the hafnium oxide film was formed by sputtering the hafnium oxide target at 20 sccm flow rate of Ar with a thickness of 5 nm.

Variable resistive element 2g:1R element having an element area of 5 μm×5 μm, wherein the hafnium oxide film was formed by sputtering the metal hafnium target at 20 sccm flow rate of Ar with addition of 4.5 sccm oxygen with a thickness of 5 nm.

Variable resistive element 2i:1T1R element having an element area of 5 μm×5 μm, wherein the hafnium oxide film was formed by sputtering the hafnium oxide target at 20 sccm flow rate of Ar with a thickness of 5 nm.

Variable resistive element 2j:1T1R element having an element area of 5 μm×5 μm, wherein the hafnium oxide film was formed by sputtering the hafnium oxide target at 20 sccm flow rate of Ar with a thickness of 4 nm.

Variable resistive element 2k:1T1R element having an element area of 5 μm×5 μm, wherein the hafnium oxide film was formed by sputtering the hafnium oxide target at 20 sccm flow rate of Ar with a thickness of 3 nm.

Variable resistive element 2l:1R element having an element area of φ50 nm, wherein the hafnium oxide film was formed by sputtering the hafnium oxide target at 20 sccm flow rate of Ar with a thickness of 5 nm.

Variable resistive element 2m:1R element having an element area of φ50 nm, wherein the hafnium oxide film was formed by sputtering the hafnium oxide target at 20 sccm flow rate of Ar with a thickness of 3 nm.

The elements having the effect of remarkably reducing the reset current are those in which the electric characteristic of the variable resistor film in the initial high resistance state before the forming process is non-linear with respect to the voltage, and current that is 1.5 to 3 digits higher than the current flowing through the sample including the ALD film with x≈2 upon the application of the same voltage flows.

The elements in which the conduction activation energy derived based upon the Poole-Frenkel model falls within the range of 0.2 to 0.4 eV provides the effect of remarkably reducing the reset current. In contrast, the conduction activation energy derived based upon the Poole-Frenkel model of the sample including the ALD film with x≈2 is about 1 eV.

### Fourth Embodiment

The result obtained by verifying the oxygen concentration of the hafnium oxide film in the above embodiments according to an electron energy-loss spectroscopy (EELS) using an electron beam with energy of 200 eV will be described below.

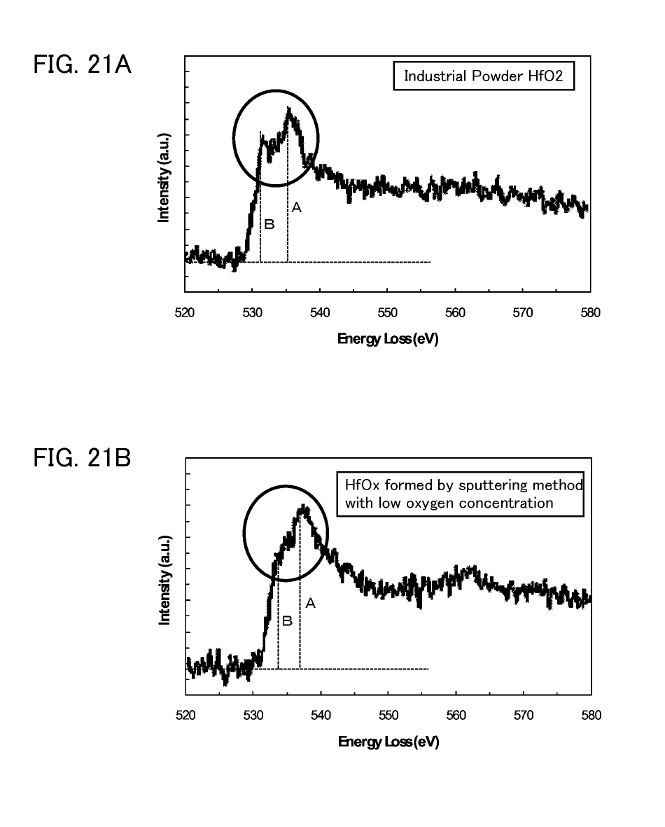

FIG. 21A shows an electron energy-loss spectrum in the vicinity of an oxygen K-absorption edge of industrial powder HfO₂, the electron energy-loss spectrum being generated by K core-excitation of oxygen. In the ideal HfO₂ containing just enough oxygen, two peaks A and B are observed between energy losses of 530 to 540 eV. This is because the second satellite peak B appears on the low-energy side due to the reflection of the crystal field splitting on 5d-orbital of Hf atom close to the excited oxygen atom. The peak A and the peak B were separately observed in the film formed by the ALD process (variable resistor film 2d) and the film formed by the sputtering method with addition of oxygen (variable resistor film 2c, 2h), that is, in the region where the stoichiometric composition ratio x of oxygen to Hf is x>1.97.

On the other hand, FIG. 21B illustrates an electron energy-loss spectrum in the vicinity of an oxygen K-absorption edge of HfOₓ formed by the sputtering method under the condition of attaining the low oxygen concentration (x<1.92). When the oxygen concentration is reduced to cause an amorphous state, the peak B on the low-energy side that can be separated disappears.

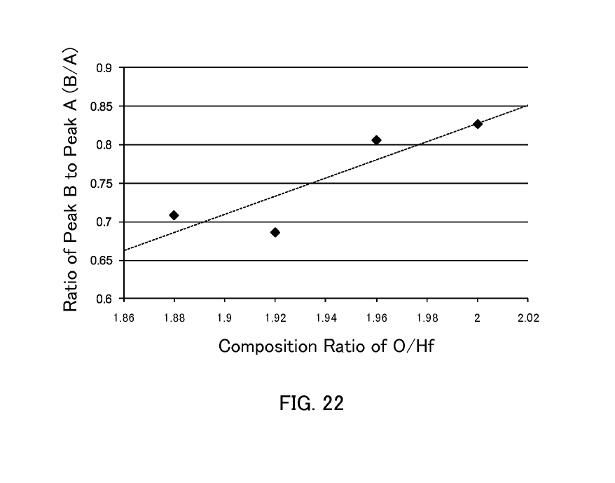

FIG. 22 illustrates the relationship between the stoichiometric composition ratio x of the hafnium oxide film and the ratio (B/A) of the intensities of the peak A and the peak B. In the cases of x=1.97, 1.92 and 1.84, the ratio of B/A becomes 0.78, 0.73, and 0.64 from the approximate line. It can be seen from this result that the hafnium oxide film having the peak intensity ratio of at least 0.78 or less is desirable in order to obtain the effect of reducing the reset current.

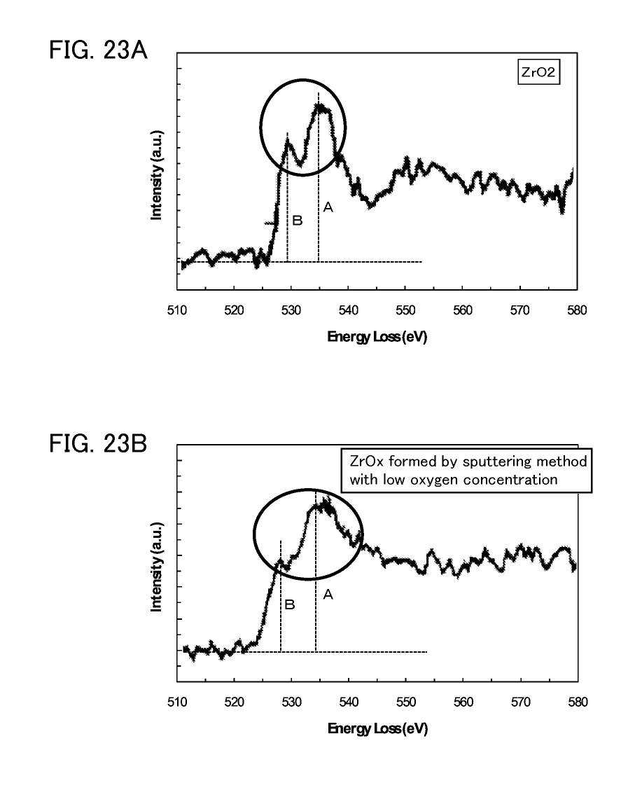

Similarly, FIGS. 23A and 23B illustrate the result of the verification of the oxygen concentration of a zirconium oxide film according to an electron energy-loss spectroscopy using an electron beam with an energy of 200 eV. FIG. 23A shows an electron energy-loss spectrum in the vicinity of an oxygen K-absorption edge of industrial powder ZrO₂, and FIG. 23B illustrates, similarly to FIG. 21B, an electron energy-loss spectrum in the vicinity of an oxygen K-absorption edge of ZrOₓ formed by the sputtering method under the condition of attaining the low oxygen concentration (x<1.92). It can be seen from FIGS. 23A and 23B that, as in HfOₓ, the intensity of the peak value of the satellite peak B on the low-energy side is reduced with the decrease in the oxygen concentration.

It is also confirmed that, as in the hafnium oxide film, in the region where the satellite peak of the energy-loss spectrum disappears, the reset current is reduced, and the satisfactory switching characteristic is obtained when it is used for the variable resistor.

Zirconium (Zr) is an element homologous with hafnium (Hf) in the periodic table. The physical properties of zirconium oxide such as band gap or coupling energy with oxygen are very similar to those of hafnium oxide. Therefore, as in hafnium oxide, even when the zirconium oxide is used for the variable resistor, the optimal range of the oxygen concentration by which the reset current can be reduced is considered to be present. Accordingly, it is considered that, when the zirconium oxide film as the variable resistor is formed in such a manner that the stoichiometric composition ratio x of oxygen to Zr falls within the range of 1.7≦x≦1.97, more preferably within the range of 1.84≦x≦1.92, the variable resistive element that can reduce the operating current and that can perform the stable switching operation can be realized.

### Fifth Embodiment

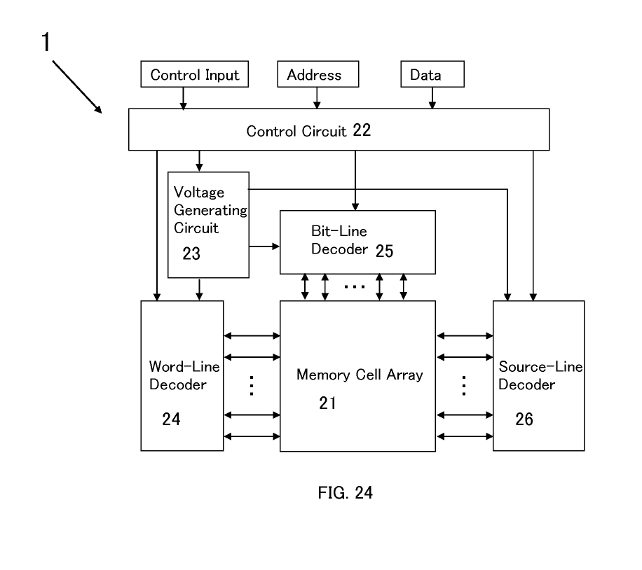

FIG. 24 illustrates one example of the present device 1 including the variable resistive element 2 (2a, 2g, 2i to 2m) of the present invention in which the oxygen concentration is adjusted. FIG. 24 is a circuit block diagram illustrating a schematic configuration of the present device 1. The present device 1 includes a memory cell array 21, a control circuit 22, a voltage generating circuit 23, a word-line decoder 24, a bit-line decoder 25, and a source-line decoder 26.

The memory cell array 21 includes a plurality of memory cells, each of which including the variable resistive element 2, in a row direction and in a column direction in a matrix. The memory cells belonging to the same column are connected by a bit line extending in the column direction, and the memory cells belonging to the same row are connected by a word line extending in the row direction.

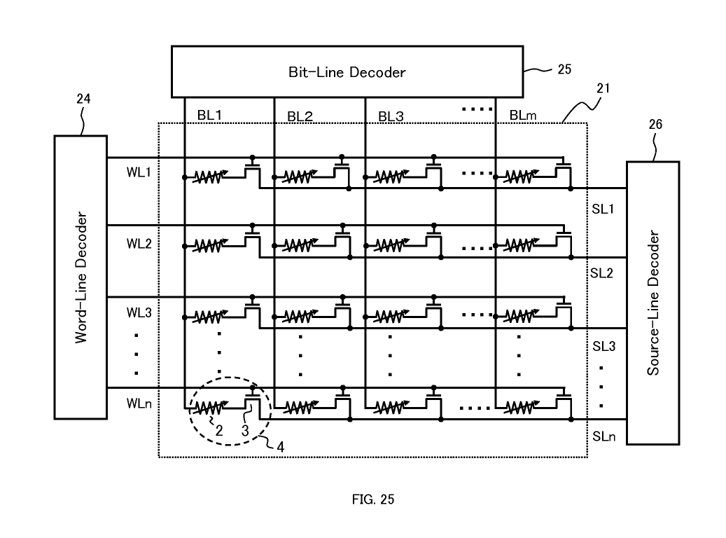

FIG. 25 is one example of an equivalent circuit diagram of the memory cell array 21. The memory cell array illustrated in FIG. 25 is a 1T1R memory cell array in which a unit memory cell includes a transistor 3 serving as a current limiting element. One electrode of the variable resistive element 2 is connected to one of a source or a drain of the transistor 3 in series to form a memory cell 4. The other electrode, not connected to the transistor 3, of the variable resistive element 2 is connected to bit lines BL1 to BLm extending in the column direction, the other one of the source and the drain of the transistor 3 that is not connected to the variable resistive element 2 is connected to source lines SL1 to SLn extending in the row direction, and the gate terminals of the transistors are connected to word lines WL1 to WLn extending in the row direction. Any one of selected word line voltage and non-selected word line voltage is applied through the word line, any one of selected bit line voltage and non-selected bit line voltage is applied through the bit line, and any one of selected source line voltage and non-selected source line voltage is applied through the source line, wherein these voltages are independently applied. With this process, one or a plurality of memory cells, which are targets of the action designated by an address input from the outside such as a programming action, erasing action, reading action, and forming process, can be selected.

The control circuit 22 controls the operation of each memory, such as the programming action (low resistance: set operation), the erasing action (high resistance: reset operation), and reading action of the memory cell array 21, and controls the forming process. Specifically, the control circuit 22 controls the word-line decoder 24, the bit-line decoder 25, and the source-line decoder 26 based upon an address signal inputted from an address line, a data input inputted from the data line, and a control input signal inputted from an a control signal line, thereby controlling the action of each memory in each memory cell and the forming process. Although not illustrated in FIG. 24, the control circuit 22 has a function of a general address buffer circuit, a data input/output circuit, and a control input buffer circuit.

The voltage generating circuit 23 generates the selected word line voltage and non-selected word line voltage necessary for selecting the target memory cell during each of the programming action (low resistance: set operation), the erasing action (high resistance: reset operation), and the reading action of the memory, and the forming process of the memory cell, and supplies the resultant to the word-line decoder 24. The voltage generating circuit 23 also generates the selected bit line voltage and non-selected bit line voltage, and supplies the resultant to the bit-line decoder 25. The voltage generating circuit 23 also generates the selected source line voltage and non-selected source line voltage, and supplies the resultant to the source-line decoder 26.

When the target memory cell is inputted to the address line to be designated during each of the programming action (low resistance: set operation), the erasing action (high resistance: reset operation), and the reading action of the memory, and the forming process of the memory cell, the word-line decoder 24 selects the word line corresponding to the address signal inputted to the address line, and respectively applies the selected word line voltage and the non-selected word line voltage to the selected word line and to the non-selected word line.

When the target memory cell is inputted to the address line to be designated during each of the programming action (low resistance: set operation), the erasing action (high resistance: reset operation), and the reading action of the memory, and the forming process of the memory cell, the bit-line decoder 25 selects the bit line corresponding to the address signal inputted to the address line, and respectively applies the selected bit line voltage and the non-selected bit line voltage to the selected bit line and to the non-selected bit line.

When the target memory cell is inputted to the address line to be designated during each of the programming action (low resistance: set operation), the erasing action (high resistance: reset operation), and the reading action of the memory, and the forming process of the memory cell, the source-line decoder 26 selects the source line corresponding to the address signal inputted to the address line, and respectively applies the selected source line voltage and the non-selected source line voltage to the selected source line and to the non-selected source line.

The detailed circuit structure of the control circuit 22, the voltage generating circuit 23, the word-line decoder 24, the bit-line decoder 25, and the source-line decoder 26 can be realized by using a known circuit structure, and the device structure of these components can be manufactured by using a known semiconductor manufacturing technique. Therefore, the detailed circuit structure, the device structure, and the manufacturing method will not be described here.

According to the present invention, the oxygen concentration of the hafnium oxide film or the zirconium oxide film used as the variable resistor is optimized, whereby the variable resistive element that can perform a stable switching operation with low voltage and low current can be realized, and a large-capacity low-power consumption non-volatile semiconductor memory device using the variable resistive element can be realized.

In the above embodiments, as the film-forming process of the variable resistor, the first embodiment describes the sputtering method using the hafnium oxide (HfO₂) containing just enough oxygen as the target, while the second embodiment describes the sputtering method using the metal hafnium as the target under the oxidation atmosphere. However, the present invention is not limited thereto. The present invention is not limited by the film-forming process, as long as the hafnium oxide film or the zirconium oxide film can be formed to have the desirable oxygen concentration. For example, the film may be formed by a sputtering method using hafnium oxide (HfOₓ) containing insufficient oxygen as the target. Although the film is formed under the argon gas atmosphere in the first and second embodiments, it is only necessary that the film is formed in an inert gas atmosphere. The inert gas is not limited to the argon gas.

Although the variable resistive element 2 having the element structure illustrated in FIG. 1 is described as one example in the above embodiments, the present invention is not limited to the element having such a structure. The present invention is applicable to a variable resistive element having any structure, as long as the oxygen concentration of the hafnium oxide film or the zirconium oxide film serving as the variable resistor is optimized within the above-mentioned range. The structure of the variable resistive element 2 is not limited by the thickness or the element area of the hafnium oxide film or the zirconium oxide film.

In the fifth embodiment of the present invention, the present device 1 can be realized by only including the variable resistive element 2 in which the oxygen concentration of the variable resistor is optimized. The present invention is not limited by the structure of the memory cell array 21 or the circuit structure of the other circuits such as the control circuit or the decoders. The memory cell array 21 may be a 1D1R memory cell array including a diode, serving as a current limiting element, in a unit memory cell, or may be a 1R memory cell array that does not contain a current limiting element in a unit memory cell array, in addition to the 1T1R memory cell array 21 illustrated in FIG. 25. In the 1D1R memory cell array, one end of the diode and one electrode of the variable resistive element are connected in series to form a memory cell, any one of the other end of the diode and the other electrode of the variable resistive element is connected to the bit line extending in the column direction, and the other one is connected to the word line extending in the row direction. In the 1R memory cell array, both electrodes of the variable resistive element are respectively connected to the bit line extending in the column direction and to the word line extending in the row direction.

The present device 1 includes the source-line decoder 26 for selecting the source lines SL1 to SLn, wherein each source line is selected to allow the voltage necessary for the operation of the memory cell to be applied. However, the source line may be shared by all memory cells, and a ground voltage (fixed potential) may be supplied to the source line. Even in this case, the voltage necessary for the operation of the memory cell can be supplied by selecting each of bit lines BL1 to BLn through the bit-line decoder 25.

The present invention is applicable to a non-volatile semiconductor memory device, and more particularly applicable to a non-volatile semiconductor memory device including a non-volatile variable resistive element whose resistance state is changed due to application of voltage, the resistance state after the change being retained in a non-volatile manner. Although the present invention has been described in terms of the preferred embodiment, it will be appreciated that various modifications and alternations might be made by those skilled in the art without departing from the spirit and scope of the invention. The invention should therefore be measured in terms of the claims which follow.

What is claimed is:

1. A non-volatile semiconductor memory device that employs a variable resistive element for storing information, the variable resistive element comprising:
a variable resistor made of a metal oxide, and
a first electrode and a second electrode that sandwich the variable resistor, an electric resistance between both electrodes of the variable resistive element being reversibly changed due to application of voltage to between the both electrodes, wherein
the first electrode is made of a conductive material and the second electrode is made of a conductive material having a different work function from that of the first electrode,
the metal oxide is hafnium oxide or zirconium oxide, and
the metal oxide has a stoichiometric composition ratio x of oxygen to a metal constituting the metal oxide, the ratio x falling within a range of 1.7≦x≦1.97.

2. The non-volatile semiconductor memory device according to claim 1, wherein the stoichiometric composition ratio x of oxygen of the metal oxide falls within a range of 1.84≦x≦1.92.

3. The non-volatile semiconductor memory device according to claim 1, wherein, in the variable resistive element, a satellite peak at a low-energy side at K-absorption edge of oxygen in an electron energy-loss spectrum of the metal oxide is not observed, or an intensity of the satellite peak at a peak position is less than 0.78 times as small as a main peak.

4. The non-volatile semiconductor memory device according to claim 1, wherein
by performing a forming process, a resistance state between the first electrode and the second electrode of the variable resistive element is changed from an initial high resistance state before the forming process to a variable resistance state;
the resistance state in the variable resistance state is changed between two or more different resistance states by application of voltage to the first electrode and the second electrode of the variable resistive element in the variable resistance state, and one of the resistance states after the change is used for storing information; and
a density of current flowing through the variable resistive element in the initial high resistance state at a time of application of an electric field of 4 MV/cm to the variable resistor falls within a range of 0.04 to 80 A/cm².

5. The non-volatile semiconductor memory device according to claim 1, wherein the first electrode is made of a conductive material having a work function smaller than 4.5 eV, and the second electrode is made of a conductive material having a work function of not less than 4.5 eV.

6. The non-volatile semiconductor memory device according to claim 5, wherein the first electrode includes any of conductive materials of Ti, Ta, Hf, and Zr.

7. The non-volatile semiconductor memory device according to claim 5, wherein the second electrode includes any of conductive materials of TiN, Pt, Ru, RuO₂, and ITO.

8. A manufacturing method of a non-volatile semiconductor memory device, the device employing a variable resistive element for storing information, the variable resistive element comprising:
a variable resistor made of a metal oxide, and a first electrode and a second electrode that sandwich the variable resistor, an electric resistance between both electrodes of the variable resistive element being reversibly changed due to application of voltage to between the both electrodes, wherein
the first electrode is made of a conductive material, and the second electrode is made of a conductive material having a different work function from that of the first electrode,
the metal oxide is hafnium oxide or zirconium oxide, and
the metal oxide has a stoichiometric composition ratio x of oxygen to a metal constituting the metal oxide, the ratio x falling within a range of 1.7≦x≦1.97, wherein the manufacturing method comprises
forming the metal oxide by a sputtering method using an oxide of a metal constituting the metal oxide or a metal constituting the metal oxide as a target under an inert gas atmosphere.

9. The manufacturing method according to claim 8, wherein the metal oxide is formed by the sputtering method using the oxide of the metal constituting the metal oxide as a target under the inert gas atmosphere not containing oxygen gas as additive gas.
